(19) United States
(12) Patent Application Publication
(10) Pub. No.: US 2015/0232990 A1
(43) Pub. Date: Aug. 20, 2015

(54) FILM FORMATION APPARATUS AND FILM FORMATION METHOD

(71) Applicant: KABUSHIKI KAISHA TOSHIBA, Minato-ku (JP)

(72) Inventors: Atsushi FUKUMOTO, Yokkaichi (JP); Fumiki AlSO, Kuwana (JP)

(73) Assignee: KABUSHIKI KAISHA TOSHIBA, Minato-ku (JP)

(21) Appl. No.: 14/457,239

(22) Filed: Aug. 12, 2014

(30) Foreign Application Priority Data
Feb. 19, 2014 (JP) 2014-029303

(51) Int. Cl. C23C 16/455; H01J 37/32; C23C 16/505

(52) U.S. Cl. CPC C23C 16/45544; C23C 16/505; H01J 37/32082; H01J 37/3244

(57) ABSTRACT

A film formation apparatus according to an embodiment includes a first chamber capable of accommodating a substrate therein and a second chamber capable of accommodating a substrate therein. A first oxygen supply system supplies oxygen to the first and second chambers simultaneously. A second oxygen supply system selectively switches a chamber, in which oxygen is supplied, at least between the first chamber and the second chamber.

### CROSS REFERENCE TO RELATED APPLICATIONS

This application is based upon and claims the benefit of priority from the prior Japanese Patent Application No. 2014-029303, filed on Feb. 19, 2014, the entire contents of which are incorporated herein by reference.

### FIELD

The embodiments of the present invention relate to a film formation apparatus and a film formation method.

### BACKGROUND

In recent years, to form patterns smaller than a minimum feature size that can be achieved by photolithography along with downscaling of semiconductor devices, there is a case of using a sidewall transfer method. In the sidewall transfer method, a core material processed by photolithography and the like is thinned by slimming and a sidewall film such as a silicon oxide film is formed on a side surface of the core material. The core material is then removed, so that a fine mask pattern constituted by the sidewall film is formed.

In a slimming process and a process of forming a sidewall film in the sidewall transfer method, an ALD (Atomic Layer Deposition) film formation apparatus is used. The ALD film formation apparatus can process the slimming process and the process of forming a sidewall film as an in situ sequence.

There is a case where the ALD film formation apparatus includes a plurality of reaction chambers. In this case, the ALD film formation apparatus includes an RF power splitter to operate the reaction chambers by an RF (Radio Frequency) power generator. The RF power splitter performs time division of RF power from the RF power generator and supply the time-divided RF power to the reaction chambers.

However, in this case, the ALD film formation apparatus cannot supply RF power to the reaction chambers simultaneously. Therefore, in the ALD film formation apparatus, while a semiconductor substrate is processed in one reaction chamber, the other reaction chamber is required to be in a standby state. For example, a core material in the sidewall transfer method is formed of a material such as SOC (Spin-On-Carbon). Therefore, there is a problem that while a slimming process is performed in one reaction chamber, a core material is altered in the other reaction chamber in a standby state. Such alteration in the core material causes an amount of slimming (a width of a core material) to be different among the reaction chambers, and this results in a variation in a distance between adjacent sidewall films.

### BRIEF DESCRIPTION OF THE DRAWINGS

FIG. 1 shows an example of a configuration of an ALD film formation apparatus 100 according to an embodiment;

FIGS. 2A to 3B are cross-sectional views of a method of forming a sidewall mask by a sidewall transfer method;

FIG. 4 is a timing diagram of RF power Prf to the first and second reaction chambers RC1 and RC2 in a slimming process and an ALD process;

FIG. 5 is a graph of an amount of sliming when the ALD film formation apparatus 100 according to the present embodiment is used;

FIG. 6 is a timing diagram when a timing of a slimming process in the first reaction chamber RC1 is made different from a timing of a slimming process in the second reaction chamber RC2; and

FIG. 7 is a graph of a result of slimming performed at a timing shown in FIG. 6.

### DETAILED DESCRIPTION

Embodiments will now be explained with reference to the accompanying drawings. The present invention is not limited to the embodiments.

A film formation apparatus according to an embodiment includes a first chamber capable of accommodating a substrate therein and a second chamber capable of accommodating a substrate therein. A first oxygen supply system supplies oxygen to the first and second chambers simultaneously. A second oxygen supply system selectively switches a chamber, in which oxygen is supplied, at least between the first chamber and the second chamber.

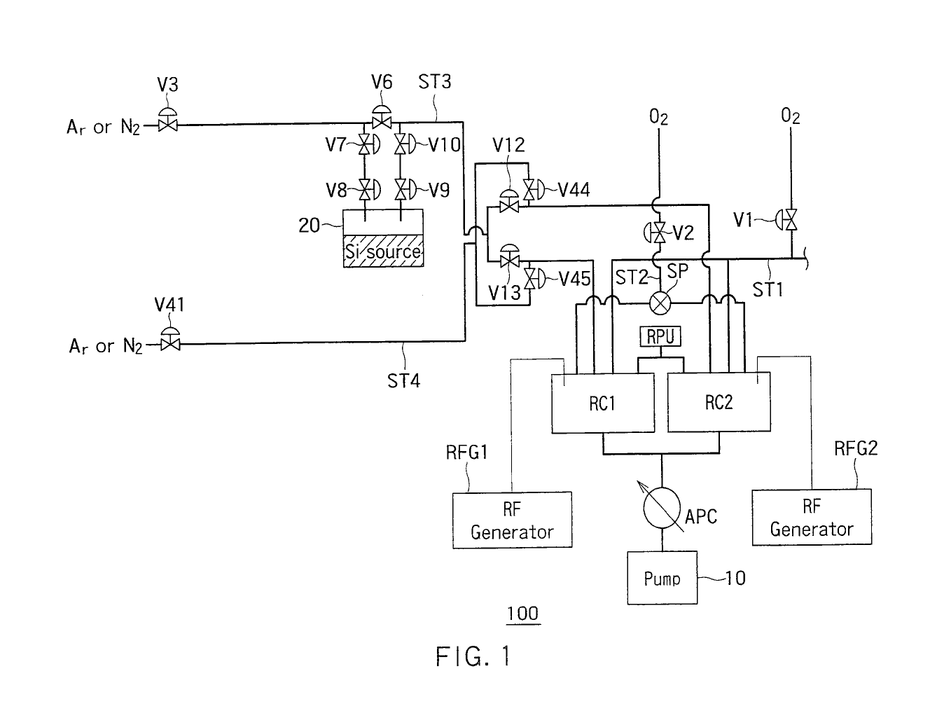

FIG. 1 shows an example of a configuration of an ALD film formation apparatus 100 (hereinafter, simply “apparatus 100”) according to an embodiment. The apparatus 100 includes a first reaction chamber RC1, a second reaction chamber RC2, an atmospheric pressure controller APC, a vacuum pump 10, a first RF generator RFG1, a second RF generator RFG2, a first oxygen supply system ST1, a second oxygen supply system ST2, a plasma generation unit RPU, an Si-gas supply system ST3, an inert-gas supply system ST4, and a silicon-source supply unit 20.

The first reaction chamber RC1 can accommodate a substrate (not shown) therein to hermetically seal the substrate. The second reaction chamber RC2 can accommodate therein a substrate to hermetically seal the substrate separately from the first reaction chamber RC1. While the first and second reaction chambers RC1 and RC2 according to the present embodiment are a single wafer chamber, a batch chamber can be also used.

The atmospheric pressure controller APC is provided between the first and second reaction chambers RC1 and RC2 and the vacuum pump 10. The atmospheric pressure controller APC controls the atmosphere within the first and second reaction chambers RC1 and RC2.

The first RF generator RFG1 supplies RF power to the first reaction chamber RC1. The second RF generator RFG2 supplies RF power to the second reaction chamber RC2 separately from the first RF generator RFG1. That is, the first RF generator RFG1 is provided to correspond to the first reaction chamber RC1, and the second RF generator RFG2 is provided to correspond to the second reaction chamber RC2. The first and second RF generators RFG1 and RFG2 can supply RF power independently to the first and second reaction chambers RC1 and RC2, respectively. The first and second RF generators RFG1 and RFG2 can also supply RF power to the respective first and second reaction chambers RC1 and RC2 simultaneously.

The first oxygen supply system ST1 is connected via a valve V1 to the first and second reaction chambers RC1 and RC2 and supplies oxygen to the first and second reaction chambers RC1 and RC2 simultaneously.

The second oxygen supply system ST2 is connected to the first and second reaction chambers RC1 and RC2 via a splitter SP, and can supply oxygen to any one of the first reaction chamber RC1 or the second reaction chamber RC2. The splitter SP can switch the reaction chamber to which oxygen is supplied between the first and second reaction chambers RC1 and RC2. The second oxygen supply system ST2 can thus supply oxygen to the first reaction chamber RC1 and the second reaction chamber RC2 sequentially or alternately. Furthermore, the second oxygen supply system ST2 includes a valve V2, and supply of oxygen to the first and second reaction chambers RC1 and RC2 can be stopped by closing the valve V2. While the first and second oxygen supply systems ST1 and ST2 are independent oxygen supply systems, oxygen supply origins (oxygen supply sources) of the first and second oxygen supply systems ST1 and ST2 can be the same.

The plasma generation unit RPU is a device that generates oxygen plasma in each of the first and second reaction chambers RC1 and RC2.

The Si-gas supply system ST3 supplies a silicon source from the silicon-source supply unit 20 to the first and second reaction chambers RC1 and RC2, respectively. Alternatively, the Si-gas supply system ST3 can supply inert gas to the first and second reaction chambers RC1 and RC2, respectively. The Si-gas supply system ST3 is connected via valves V3 to V13 to the silicon-source supply unit 20 and the first and second reaction chambers RC1 and RC2.

The inert-gas supply system ST4 supplies inert gas to the first and second reaction chambers RC1 and RC2, respectively. For example, the inert gas supplied from the gas supply systems ST3 and ST4 can be argon, nitrogen, or helium. The inert-gas supply system ST4 is connected via valves V41 to V45 to the first and second reaction chambers RC1 and RC2.

The silicon-source supply unit 20 includes a container for storing therein a silicon source and a temperature control unit controlling the temperature of the silicon source. The silicon-source supply unit 20 is connected via valves V7 to V11 to the Si-gas supply system ST3 and can supply vaporized silicon source gas to the first and second reaction chambers RC1 and RC2. Alternatively, the vaporized silicon source gas can be supplied to the first and second reaction chambers RC1 and RC2 by an injection valve.

The apparatus 100 according to the present embodiment includes a plurality of reaction chambers RC1 and RC2. The first oxygen supply system ST1 supplies oxygen to the reaction chambers RC1 and RC2 simultaneously. The second oxygen supply system ST2 selectively switches the chamber to which oxygen is supplied between the first reaction chamber RC1 and the second reaction chamber RC2 by the splitter SP. The apparatus 100 also includes the RF generators RFG1 and RFG2 corresponding to the first and second reaction chambers RC1 and RC2, respectively. Therefore, as described later, in a sidewall transfer method, slimming of a core material on a substrate can be performed in the first and second reaction chambers RC1 and RC2 simultaneously. Further, the material for a sidewall film can be deposited on the core material having been subjected to the slimming sequentially or alternately by ALD.

The number of reaction chambers can be equal to or more than three. In this case, the first oxygen supply system ST1 supplies oxygen to all reaction chambers simultaneously. The second oxygen supply system ST2 can supply oxygen to any of the reaction chambers sequentially or selectively by the splitter SP. The number of the RF generators to be provided is equal to the number of reaction chambers.

According to the apparatus 100 of the present embodiment, at the time of slimming (etching) of a core material 30, the first oxygen supply system ST1 supplies oxygen to the first and second reaction chambers RC1 and RC2 simultaneously, and the RF generators RFG1 and RFG2 supply RF power to the first and second reaction chambers RC1 and RC2 simultaneously. With this configuration, the apparatus 100 can perform slimming of the core material 30 in the first and second reaction chambers RC1 and RC2 concurrently. As a result, the degree of alteration in the core material 30 in the first reaction chamber RC1 can be substantially equal to that in the second reaction chamber RC2, and the amount of slimming (the width of a core material) in the first reaction chamber RC1 can be the same as that in the second reaction chamber RC2. That is, in the apparatus 100, a variation in the width of the core material 30 between chambers (RC1 and RC2) is very small. Therefore, distances on a mask pattern of a sidewall film 40 also can be formed substantially uniformly (as designed) with a small variation.

Furthermore, in the apparatus 100, the second oxygen supply system ST2 that is provided separately from the first oxygen supply system ST1 selectively supplies oxygen to the first reaction chamber RC1 or the second reaction chamber RC2. Therefore, according to the apparatus 100, the material for a sidewall film can be deposited on a side surface of a core material sequentially or alternately in an ALD process to be explained later.

Next, a film formation method by using the apparatus 100 according to the present embodiment is explained.

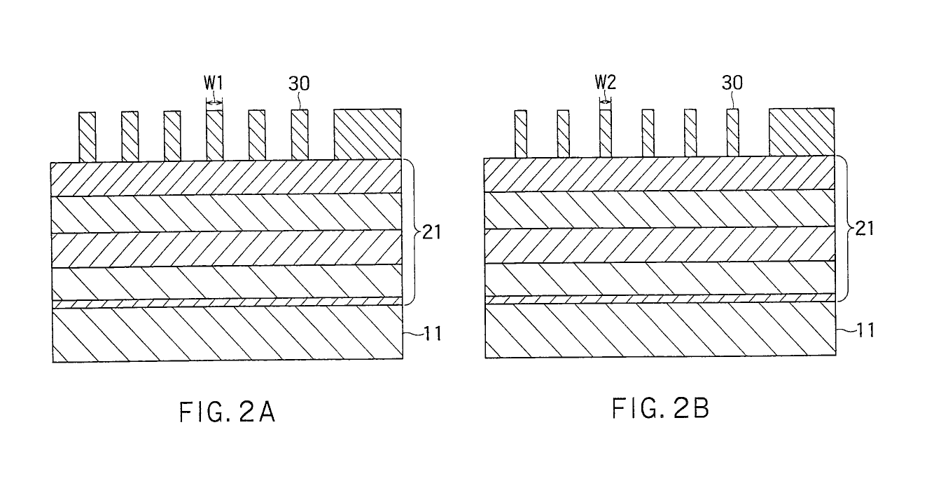

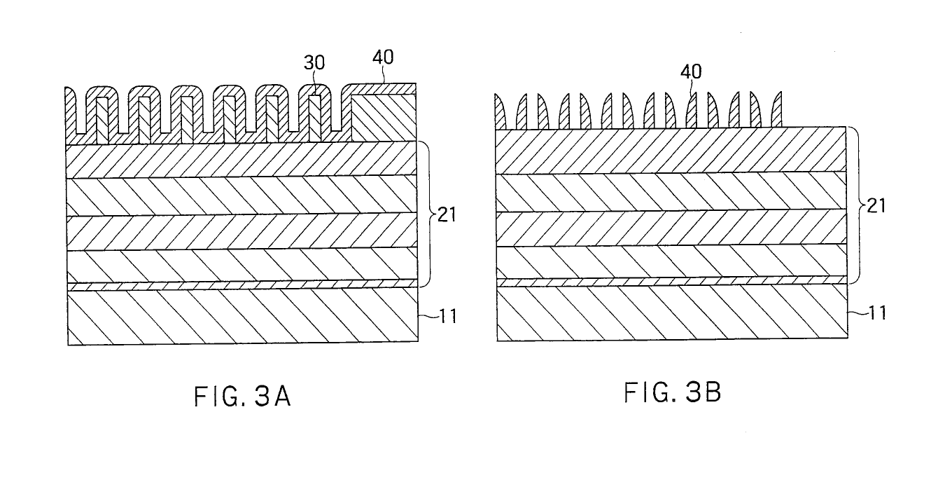

FIGS. 2A to 3B are cross-sectional views of a method of forming a sidewall mask by a sidewall transfer method. A slimming process shown in FIG. 2B and a process of depositing a sidewall film (ALD) shown in FIG. 3A are performed in the apparatus 100.

As shown in FIG. 2A, a processing target film 21 is formed on a substrate 11. For example, the processing target film 21 can be a material for a tunnel dielectric film, a charge accumulation layer, a gate dielectric film, a control gate, and a hard mask in a NAND flash memory. It is needless to mention that the processing target film 21 is not limited to the material for a NAND flash memory, and can be those for other semiconductor devices.

Next, the material for the core material 30 is deposited on the processing target film 21. The core material 30 is then processed by lithography and etching (RIE (Reactive Ion Etching)). As a result, as shown in FIG. 2A, a convex core material 30 is formed on the processing target film 21. The core material 30 is used as a core at the time of forming a mask pattern (a sidewall film) by a sidewall transfer method. For example, the core material 30 is formed of an SOC (Spin On Carbon) film. The SOC film contains carbon and can be etched (subjected to slimming) by using oxygen plasma. The amount of slimming can be also adjusted by adjusting the time of slimming.

Next, two substrates 11 are put in the first reaction chamber RC1 and the second reaction chamber RC2, respectively, and are hermetically sealed therein. Next, as shown in FIG. 2B, slimming is performed on the core material 30. With this slimming process, the core material 30 is etched so that the width of the core material 30 becomes narrow. For example, a width W1 of the core material 30 before slimming becomes a width W2 after slimming (W2<W1) (see FIGS. 2A and 2B). To adjust a dimensional variation in W2 between wafers, the time of slimming is varied depending on a difference between a dimension value of the width W1 and a target dimension value of the width W2.

In the slimming process, the apparatus 100 uses oxygen plasma to oxidize the core material 30, thereby etching the core material 30. Detailed operations of the apparatus 100 in the slimming process are explained later.

Next, the material for the sidewall film 40 is deposited on a top surface and a side surface of the core material 30 by ALD, while the substrates 11 are kept in the first reaction chamber RC1 and the second reaction chamber RC2. At this time, the material for the sidewall film 40 does not completely fill a space between adjacent core materials 30. As a result, as shown in FIG. 3A, a side surface of the core material 30 is coated with the material for the sidewall film 40. For example, the material for the sidewall film 40 is an insulation film such as a silicon oxide film.

In a process of depositing the sidewall film 40, the apparatus 100 repeats a step of using a silicon source to coat a surface of the core material 30 with an atomic-level silicon film and a step of using oxygen plasma to oxidize a silicon film. With this process, a silicon oxide film is formed on the surface of the core material 30. Detailed operations of the apparatus 100 in the process of depositing the sidewall film 40 (hereinafter, also “ALD process”) are explained later.

Next, the sidewall film 40 is anisotropically etched by an etching apparatus. The sidewall film 40 thus remains on a side surface of the core material 30. Furthermore, by selectively removing the core material 30, a mask pattern constituted by the sidewall film 40 is formed. Next, the processing target film 21 is processed by using the sidewall film 40 as a mask. As a result, for example, a fine gate structure of a NAND flash memory can be obtained.

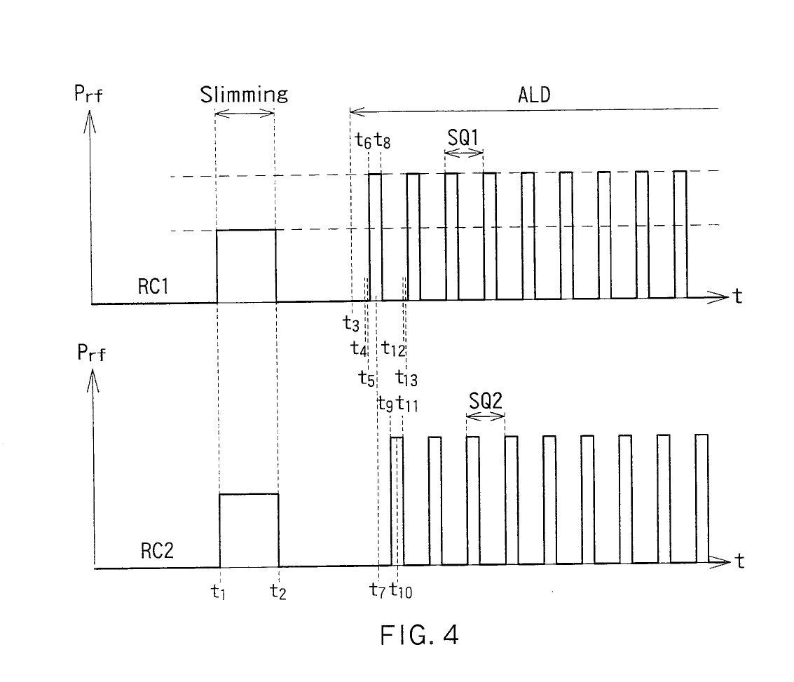

FIG. 4 is a timing diagram of RF power Prf to the first and second reaction chambers RC1 and RC2 in a slimming process and an ALD process. Operations of the apparatus 100 in the slimming process and the ALD process are explained in detail with reference to FIG. 4 as well as FIG. 1.

### Slimming Process

At t1 to t2, the apparatus 100 performs a slimming process. In the slimming process, the apparatus 100 etches (performs slimming on) the core materials 30 simultaneously in the first and second reaction chambers RC1 and RC2. Therefore, the valve V1 in the first oxygen supply system ST1 is opened, and the first oxygen supply system ST1 supplies oxygen to the first and second reaction chambers RC1 and RC2 simultaneously.

The first and second RF generators RFG1 and RFG2 supply RF power to the respective first and second reaction chambers RC1 and RC2 simultaneously, so that oxygen plasma is generated in these chambers. With this process, the core material 30 is gradually oxidized by oxygen plasma and etched in the first and second reaction chambers RC1 and RC2 simultaneously. At t2, the apparatus 100 ends slimming.

When the number of reaction chambers is equal to or more than three, it suffices that the first oxygen supply system ST1 supplies oxygen to all the reaction chambers simultaneously, and the RF generators supply RF power to all the reaction chambers simultaneously.

### ALD Process

Next, at t3, the apparatus 100 starts an ALD process. In the ALD process, the apparatus 100 performs a step of feeding silicon source gas, a step of purging silicon source gas, a step of oxidizing a silicon film on the core material 30, and a step of purging oxygen gas repeatedly as an in situ sequence (hereinafter, also “ALD sequence”). With this process, an atomic-level silicon oxide layer is coated repeatedly and a silicon oxide film is deposited on a surface of the core material 30.

The ALD sequence is performed in the first and second reaction chambers RC1 and RC2 repeatedly and alternately. However, as shown in FIG. 4, an ALD sequence SQ1 in the first reaction chamber RC1 is shifted from an ALD sequence SQ2 in the second reaction chamber RC2 by a half period.

For example, the ALD sequences SQ1 and SQ2 are performed as follows. In an initial state, inert gas (argon or nitrogen) is supplied to the first and second reaction chambers RC1 and RC2. At this time, the valves V3, V6 and V13 are opened and the valves V7 to V10 and V12 are closed in the Si-gas supply system ST3. Therefore, the Si-gas supply system ST3 supplies inert gas to the first reaction chamber RC1. The valves V41 and V44 are opened and the valve V45 is closed in the inert-gas supply system ST4. Therefore, the inert-gas supply system ST4 supplies inert gas to the second reaction chamber RC2. The valve V1 in the oxygen supply system ST1 and the valve V2 in the oxygen supply system ST2 are closed. In this case, the first and second RF generators RFG1 and RFG2 are switched off.

Next, a feed step in the first reaction chamber RC1 is performed (t3 to t4). At the feed step in the first reaction chamber RC1, the valve V6 is closed and the valves V7 to V10 are opened in the Si-gas supply system ST3. The Si-gas supply system ST3 thus causes inert gas to flow via the silicon-source supply unit 20 in the first reaction chamber RC1. Accordingly, silicon source gas is introduced in the first reaction chamber RC1 with the inert gas. In the first reaction chamber RC1, a surface of the core material 30 is coated with an atomic-level silicon film. At this time, the inert-gas supply system ST4 continues to supply inert gas to the second reaction chamber RC2.

Next, a purge step in the first reaction chamber RC1 is performed (t4 to t6). At the purge step in the first reaction chamber RC1, the valves V7 and V10 are closed and the valve V6 is opened in the Si-gas supply system ST3. The Si-gas supply system ST3 thus causes inert gas to flow in the first reaction chamber RC1 to substitute silicon source gas remaining within the first reaction chamber RC1 with the inert gas. It is needless to mention that a silicon film formed on the surface of the core material 30 remains. At t4, the inert-gas supply system ST4 continues to supply the inert gas to the second reaction chamber RC2.

Next, a feed step in the second reaction chamber RC2 is performed (t5 to t7). At the feed step in the second reaction chamber RC2, the valves V6 and v13 are closed and the valves V7 to V10 and V12 are opened in the Si-gas supply system ST3. The Si-gas supply system ST3 thus causes inert gas to flow via the silicon-source supply unit 20 in the second reaction chamber RC2. Accordingly, silicon source gas is introduced in the second reaction chamber RC2 with the inert gas. In the second reaction chamber RC2, an atomic-level silicon film is formed on the surface of the core material 30. Meanwhile, the valve V44 is closed and the valve V45 is opened in the inert-gas supply system ST4. Accordingly, the inert-gas supply system ST4 supplies the inert gas to the first reaction chamber RC1. That is, at t5, the purge step in the first reaction chamber RC1 is continued.

Next, an oxidization step in the first reaction chamber RC1 is performed (t6 to t8). At the oxidization step in the reaction chamber RC1, the valve V2 in the second oxygen supply system ST2 is opened, and the splitter SP connects the second oxygen supply system ST2 to the first reaction chamber RC1. The second oxygen supply system ST2 thus supplies oxygen to the first reaction chamber RC1. At this time, the first RF generator RFG1 is switched on to supply RF power to the first reaction chamber RC1. Accordingly, oxygen plasma is generated in the first reaction chamber RC1 to oxidize a silicon film formed on the surface of the core material 30. As a result, an atomic-level silicon oxide layer is formed on the surface of the core material 30 within the first reaction chamber RC1. At t6, the feed step in the second reaction chamber RC2 is continued.

Next, a purge step in the second reaction chamber RC2 is performed (t7 to t9). At the purge step in the second reaction chamber RC2, the valves V7 and V10 are closed and the valve V6 is opened in the Si-gas supply system ST3. The Si-gas supply system ST3 thus causes inert gas to flow in the second reaction chamber RC2 to substitute silicon source gas remaining within the second reaction chamber RC2 with the inert gas. It is needless to mention that a silicon film formed on the surface of the core material 30 remains. At t7, the oxidization step in the first reaction chamber RC1 is continued.

Next, when the oxidization in the first reaction chamber RC1 ends at t8, the first RF generator RFG1 is switched off and the valve V2 in the second oxygen supply system ST2 is closed.

Next, a purge step in the first reaction chamber RC1 is performed (t8 to t10). At the purge step in the reaction chamber RC1, the valve V12 is closed and the valve V13 is opened in the Si-gas supply system ST3. The Si-gas supply system ST3 thus causes inert gas to flow in the first reaction chamber RC1 to substitute oxygen gas remaining within the first reaction chamber RC1 with the inert gas. The valve V45 is closed and the valve V44 is opened in the inert-gas supply system ST4. The inert-gas supply system ST4 thus supplies inert gas to the second reaction chamber RC2. That is, at t8, the purge step in the second reaction chamber RC2 is continued.

Next, an oxidization step in the second reaction chamber RC2 is performed (t9 to t11). At the oxidization step in the second reaction chamber RC2, the valve V2 is opened in the second oxygen supply system ST2, and the splitter SP connects the second oxygen supply system ST2 to the second reaction chamber RC2. The second oxygen supply system ST2 thus causes oxygen to flow in the second reaction chamber RC2. At this time, the second RF generator RFG2 is switched on to supply RF power to the second reaction chamber RC2. Accordingly, oxygen plasma is generated in the second reaction chamber RC2 to oxidize a silicon film formed on the surface of the core material 30. As a result, an atomic-level silicon oxide layer is formed on the surface of the core material 30 within the second reaction chamber RC2. At t9, the purge step is continued in the first reaction chamber RC1.

Next, the feed step in the first reaction chamber RC1 is started again (t10 to t12). This feed step is identical to the feed step at t3 to t4. At t10, the oxidization step in the second reaction chamber RC2 is continued.

Next, when the oxidization step in the second reaction chamber RC2 ends at t11, the second RF generator RFG2 is switched off, and the valve V2 in the second oxygen supply system ST2 is closed.

Next, a purge step in the second reaction chamber RC2 is performed (t11 to t13). At the purge step in the second reaction chamber RC2, a state where the valve V45 is closed and the valve V44 is opened in the inert-gas supply system ST4 is kept. Accordingly, the inert-gas supply system ST4 supplies inert gas to the second reaction chamber RC2. At t11, the feed step in the first reaction chamber RC1 is continued.

When the purge step in the second reaction chamber RC2 ends, the feed step in the second reaction chamber RC2 is started again at t13. This feed step is identical to the feed step at t5 to t7.

In this manner, the ALD sequence SQ1 (t3, t4, t6, t8, and t10) in the first reaction chamber RC1 and the ALD sequence SQ2 (t5, t7, t9, t11, and t13) in the second reaction chamber RC2 are performed repeatedly and alternately while being shifted by a half period. In this manner, the silicon oxide film 40 shown in FIG. 3A is formed.

When the number of reaction chambers is n (n is an integer equal to or larger than 3), it suffices that ALD sequences of the respective reaction chambers are shifted from each other by a 1/n period. At this time, it suffices that the second oxygen supply system ST2 supplies oxygen to the respective reaction chambers sequentially or selectively while shifting by a 1/n period.

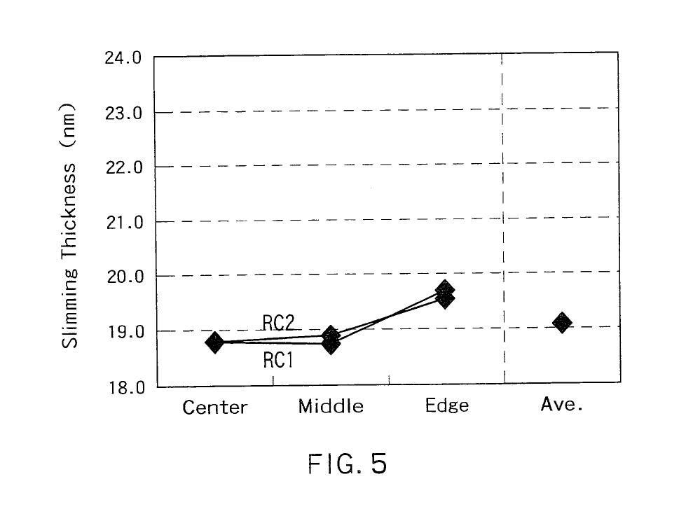

FIG. 5 is a graph of an amount of sliming when the ALD film formation apparatus 100 according to the present embodiment is used. In FIG. 5, the vertical axis indicates an amount of slimming (a line width of the etched core material 30), and the horizontal axis indicates an in-plane position of the substrate 11.

When slimming is performed on the core material 30 by the apparatus 100, the amount of slimming in the first reaction chamber RC1 is substantially equal to that in the second reaction chamber RC2. That is, there is only a slight variation between the width of the core material 30 processed in the first reaction chamber RC1 and the width of the core material 3C) processed in the second reaction chamber RC2. The same holds true for any in-plane position of the substrate 11 and an average (Avg.) thereof.

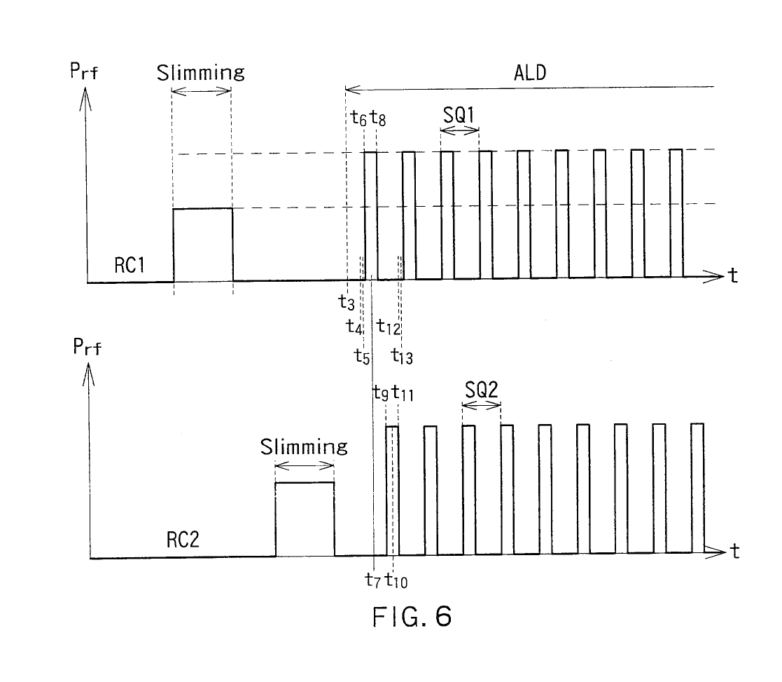

FIG. 6 is a timing diagram when a timing of a slimming process in the first reaction chamber RC1 is made different from a timing of a slimming process in the second reaction chamber RC2. In this case, after slimming is performed in the first reaction chamber RC1, slimming is performed in the second reaction chamber RC2. Other operations in the ALD process in FIG. 6 can be identical to those of the apparatus 100 according to the present embodiment.

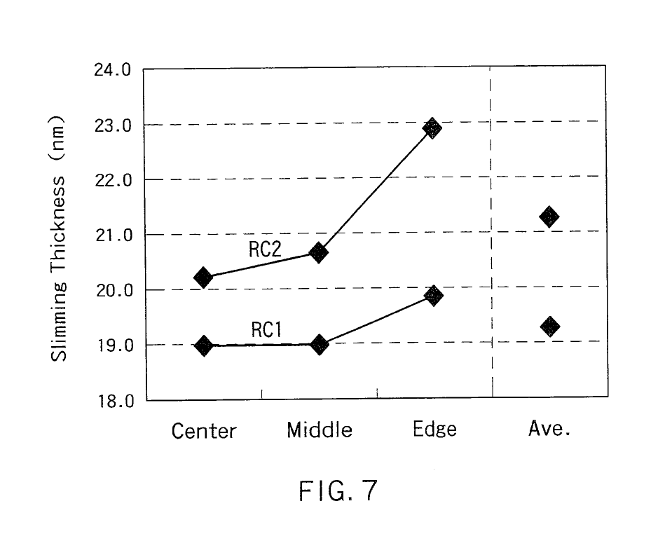

FIG. 7 is a graph of a result of slimming performed at a timing shown in FIG. 6. When slimming is performed on the core material 30 at the timing shown in FIG. 6, there is a large variation between the amount of slimming in the first reaction chamber RC1 and the amount of slimming in the second reaction chamber RC2. The same holds true for any in-plane position of the substrate 11 and an average (Avg.) thereof.

As explained above, the apparatus 100 according to the present embodiment supplies oxygen and RF power to the respective first and second reaction chambers RC1 and RC2 simultaneously at the time of slimming (etching) of the core material 30. With this configuration, the apparatus 100 performs slimming of the core material 30 in the first and second reaction chambers RC1 and RC2 concurrently. As a result, the degree of alternation in the core material 30 in the first reaction chamber RC1 can be substantially equal to that in the second reaction chamber RC2, and the slimming amount (the width of a core material) in the first reaction chamber RC1 can be the same as that in the second reaction chamber RC2. That is, in the apparatus 100, the variation in the width of the core material 30 between chambers (RC1 and RC2) is very small. Accordingly, distances on a mask pattern of the sidewall film 40 can be also formed substantially uniformly (as designed) with only a small variation.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A film formation apparatus comprising:
a first chamber capable of accommodating a substrate therein;
a second chamber capable of accommodating a substrate therein;
a first oxygen supply system supplying oxygen to the first and second chambers simultaneously; and
a second oxygen supply system selectively switching a chamber, in which oxygen is supplied, at least between the first chamber and the second chamber.

2. The apparatus of claim 1, further comprising a switching unit provided in the second oxygen supply system and selectively switching a chamber, in which oxygen is supplied, at least between the first chamber and the second chamber.

3. The apparatus of claim 1, further comprising:
a first power supply unit supplying power to the first chamber; and
a second power supply unit supplying power to the second chamber separately from the first power supply unit.

4. The apparatus of claim 2, further comprising:
a first power supply unit supplying power to the first chamber; and
a second power supply unit supplying power to the second chamber separately from the first power supply unit.

5. The apparatus of claim 1, further comprising a first power supply unit and a second power supply unit that are provided to correspond to the respective first and second chambers, the first and second power supply units being capable of supplying power to the respective first and second chambers simultaneously.

6. The apparatus of claim 2, further comprising a first power supply unit and a second power supply unit that are provided to correspond to the respective first and second chambers, the first and second power supply units being capable of supplying power to the respective first and second chambers simultaneously.

7. The apparatus of claim 1, wherein at least the first chamber and the second chamber use the second oxygen supply system to perform a film formation process sequentially or alternately.

8. The apparatus of claim 2, wherein at least the first chamber and the second chamber use the second oxygen supply system to perform a film formation process sequentially or alternately.

9. The apparatus of claim 3, wherein at least the first chamber and the second chamber use the second oxygen supply system to perform a film formation process sequentially or alternately.

10. The apparatus of claim 1, wherein
the first chamber and the second chamber use the first oxygen supply system to etch a material on each of the substrates simultaneously, and
the first chamber and the second chamber use the second oxygen supply system to perform a film formation process on the material on each of the substrates sequentially or alternately.

11. The apparatus of claim 2, wherein
the first chamber and the second chamber use the first oxygen supply system to etch a material on each of the substrates simultaneously, and
the first chamber and the second chamber use the second oxygen supply system to perform a film formation process on the material on each of the substrates sequentially or alternately.

12. The apparatus of claim 3, wherein
the first chamber and the second chamber use the first oxygen supply system to etch a material on each of the substrates simultaneously, and
the first chamber and the second chamber use the second oxygen supply system to perform a film formation process on the material on each of the substrates sequentially or alternately.

13. A film formation method using a film formation apparatus, the apparatus comprising a first oxygen supply system capable of supplying oxygen to a first chamber and a second chamber simultaneously, and a second oxygen supply system capable of switching a chamber, in which oxygen is supplied, at least between the first chamber and the second chamber,
the method comprising:
using the first oxygen supply system and etching a material on each of substrates in the first and second chambers simultaneously; and
using the second oxygen supply system and performing a film formation process on the material on each of the substrates at least in the first and second chamber sequentially or alternately.

14. The method of claim 13, wherein
at a time of the etching, the film formation apparatus supplies power to the first and second chambers simultaneously, and
at a time of the film formation process, the film formation apparatus supplies power to the first and second chambers sequentially or alternately.

15. The method of claim 13, wherein
the material on each of the substrates in the first and second chambers is a convex core material used for forming a mask pattern,
at a time of the etching, the film formation apparatus reduces a width of the core material, and
at a time of the film formation process, the film formation apparatus performs film formation of a material for the mask pattern on a side surface of the core material.

16. The method of claim 14, wherein
the material on each of the substrates in the first and second chambers is a convex core material used for forming a mask pattern,
at a time of the etching, the film formation apparatus reduces a width of the core material, and
at a time of the film formation process, the film formation apparatus performs film formation of a material for the mask pattern on a side surface of the core material.
